(19) United States
(12) Patent Application Publication
(10) Pub. No.: US 2021/0408436 A1
(43) Pub. Date: Dec. 30, 2021

(54) DISPLAY PANEL AND METHOD OF MANUFACTURING THEREOF

(71) Applicant: Wuhan China Star Optoelectronics Semiconductor Display Technology Co., Ltd., Wuhan (CN)

(72) Inventor: Yuanyuan ZHAO, Wuhan (CN)

(73) Assignee: Wuhan China Star Optoelectronics Semiconductor Display Technology Co., Ltd., Wuhan (CN)

(21) Appl. No.: 16/652,676

(22) PCT Filed: Feb. 14, 2020
(86) PCT No.: PCT/CN2020/075255

§ 371 Date: Apr. 1, 2020

(30) Foreign Application Priority Data
Aug. 29, 2019 (CN) 201910807097.X

(51) Int. Cl. H01L 51/52; H01L 51/56

(52) U.S. Cl. CPC H01L 51/5225; H01L 51/5234; H01L 27/3244; H01L 2251/558; H01L 51/56

(57) ABSTRACT

A display panel and a method of manufacturing thereof are provided. The display panel includes pixel regions spaced from each other and arranged in an array and a space region disposed between the pixel regions. The display panel includes a thin film transistor substrate, a cathode layer, and a functional layer disposed in order, and a thickness of the cathode layer above the pixel region is less than a thickness of the cathode layer above the space region.

### CROSS-REFERENCE TO RELATED APPLICATIONS

The present application claims priority to Chinese Patent Application No. 201910807097.X, filed on Aug. 29, 2019, filed for the invention titled “Display Panel and Method of Manufacturing Thereof”, which is hereby incorporated by reference in its entirety.

### BACKGROUND OF INVENTION

### Field of Invention

The present invention relates to the field of display panel technology, and more particularly, to a display panel and a method of manufacturing thereof.

### Description of Prior Art

Organic light emitting diode (OLED) displays are attractive to many display manufacturers around the world because they have advantages, such as actively emitting light, working at low temperatures, fast response times, wide viewing angles, high luminous efficiency, flexible, and low driving voltage, and low energy consumption. Therefore, they are considered as the next-generation display technology.

With the rapid development of new display technologies, OLED display devices are given more expectations, such as a wide color gamut, high contrast, low energy consumption, high resolution, etc. In the currently top-emitting display panel, magnesium/silver alloy is mainly used as a translucent cathode material. In order to reduce the cathode's absorption of light and reduce the loss of light efficiency, a thickness of the cathode is usually thin, which is about 120 nm, but if the thickness of the cathode is too thin, the resistance of the cathode will be raised, that is, the IR drop of the display panel will be raised. In order to ensure the brightness uniformity of the display panel, an external voltage needs to be increased. As a result, energy consumption of the display panel increases.

Therefore, it is really necessary to develop a new method of manufacturing a display panel to overcome the defects in the prior art.

### SUMMARY OF INVENTION

An object of the present invention is to provide a display panel that solves the problem of voltage drop caused by a thin cathode in a display panel in the prior art.

A display panel comprises pixel regions spaced from each other and arranged in an array, and a space region disposed between the pixel regions. The display panel comprises a thin film transistor substrate, a cathode layer, and a functional layer disposed in order, and a thickness of the cathode layer above the pixel region is less than a thickness of the cathode layer above the space region.

In one embodiment, the thickness of the cathode layer above the pixel region ranges from 100 nm to 150 nm.

In one embodiment, the thickness of the cathode layer above the space region ranges from 400 nm to 600 nm.

In one embodiment, a material of the cathode layer comprises one of magnesium alloys or silver alloys.

In one embodiment, a light transmittance of the cathode layer above the pixel region is greater than 90%.

A method of manufacturing the display panel comprises following steps:

step S1: providing a thin film transistor substrate, and the thin film transistor substrate comprises pixel regions spaced from each other and arranged in an array and a space region disposed between the pixel regions, and a first cathode layer is deposited on the thin film transistor substrate by vapor deposition;

step S2: forming a maleic anhydride layer on the first cathode layer located in the pixel region;

step S3: forming a second cathode layer between the pixel region and the space region by vapor deposition, and the second cathode layer is disposed on the maleic anhydride layer in the pixel region.

step S4: stripping the maleic anhydride layer from the second cathode layer above the pixel region are, and the first cathode layer formed in step S1 is retained at the pixel region, and the first cathode layer contacted with the second cathode layer is simultaneously retained in the space region; and

step S5: forming a functional layer.

In one embodiment, the first cathode layer is evaporated by using an open mask in the step S1.

In one embodiment, the maleic anhydride layer is formed above the pixel region by inkjet printing in the step S2.

In one embodiment, the second cathode layer is evaporated by using an open mask in the step S3.

In one embodiment, a thickness of the first cathode layer ranges from 100 nm to 150 nm.

In one embodiment, a thickness of the second cathode layer ranges from 300 nm to 500 nm.

Compared with the prior art, the present invention has beneficial effects described herein. A display panel and a method of manufacturing thereof are provided. The thickness of the cathode layer above the pixel region is less than the prior art, and the use of a highly transparent material as the cathode may improve the transmittance of the display panel. The thickness of the cathode layer above the space region is great than the prior art, which avoids the problem of voltage drop, thereby avoiding raising the external voltage and achieving the purpose of reducing energy consumption. In addition, the method is simple, easy to implement, and operability.

### BRIEF DESCRIPTION OF DRAWINGS

In order to more clearly illustrate the technical solutions in the embodiments, the drawings described in the description of the embodiments are briefly described below. It is obvious that the drawings in the following description are only some embodiments of the present invention. Other drawings can also be obtained from those skilled persons in the art based on drawings without any creative effort.

FIG. 1 is a schematic structural view of a display panel according to first embodiment of the present invention.

FIG. 2 is a flowchart of a method of manufacturing a display panel according to first embodiment of the present invention.

FIG. 3 is a schematic structural view of a display panel in step S1 of the manufacturing method according to first embodiment of the present invention.

FIG. 4 is a schematic structural view of a display panel in step S2 of the manufacturing method according to first embodiment of the present invention.

FIG. 5 is a schematic structural view of a display panel in step S3 of the manufacturing method according to first embodiment of the present invention.

FIG. 6 is a schematic structural view of a display panel in step S4 of the manufacturing method according to first embodiment of the present invention.

FIG. 7 is a schematic structural view of a display panel in step S5 of the manufacturing method according to first embodiment of the present invention.

### DETAILED DESCRIPTION OF PREFERRED EMBODIMENTS

In the following, the technical solutions will be clearly and completely described with reference to the drawings in the embodiments of the present invention. Obviously, the described embodiments are only a part of the embodiments of the present invention, but not all the embodiments. Based on the embodiments of the present invention, all other embodiments obtained by a skilled person in the art without creative efforts shall fall within the claimed scope of the present invention.

The specific structural and functional details disclosed herein are merely representative and are used for the purpose of describing exemplary embodiments of the present invention. The invention may, however, be embodied in many alternative forms and should not be construed as limited to the embodiments set forth herein.

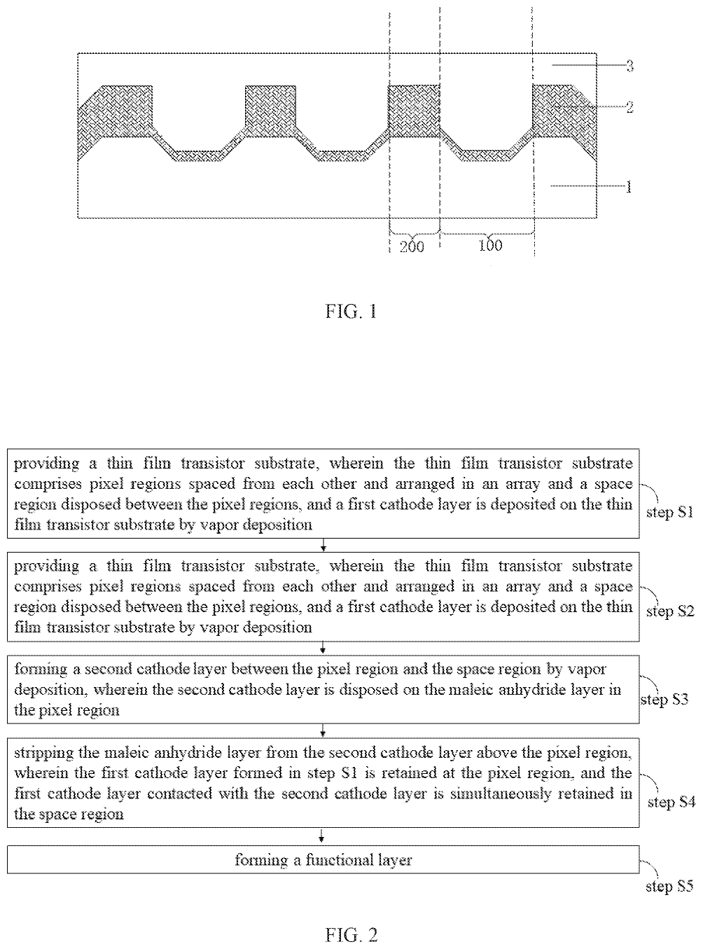

In first embodiment, a display panel is provided. Referring to FIG. 1, it is a schematic structural view of a display panel according to first embodiment of the present invention. The display panel includes pixel regions 100 spaced from each other and arranged in an array and a space region 200 disposed between the pixel regions 100.

The display panel includes a thin film transistor substrate 1, a cathode layer 2 disposed on a back plate of the thin film transistor substrate 1, and a functional layer 3 disposed on the cathode layer 2

A thickness of the cathode layer 2 above the pixel region 100 is less than a thickness of the cathode layer 2 above the space region 200. The thickness of the cathode layer 2 above the pixel region 100 ranges from 100 nm to 150 nm. The thickness of the cathode layer 2 above the space region 200 ranges from 400 nm to 600 nm.

The cathode layer 2 is made of magnesium alloys or silver alloys, which is not limited herein.

The thickness of the cathode layer 2 above the pixel region 100 is less than the prior art, and its light transmittance is greater than 90%, which raises the light transmittance of the display panel. The thickness of the cathode layer 2 above the space region 200 is great than the prior art, and the cathode layer 2 is opaque.

Because the thickness of the cathode layer 2 above the space region 200 is great than the prior art, the problem of voltage drop may be avoided, thereby avoiding raising the external voltage, so as to reduce the energy consumption.

In another embodiment, a method of manufacturing the display panel is provided. Referring to FIG. 2, it is a flowchart of a method of manufacturing a display panel according to first embodiment of the present invention.

The method of manufacturing a display panel includes steps as follows:

Step S1: providing a thin film transistor substrate 1, and the thin film transistor substrate includes pixel regions 100 spaced from each other and arranged in an array and a space region 200 disposed between the pixel regions 100, and a first cathode layer 21 is deposited on the thin film transistor substrate 1 by vapor deposition.

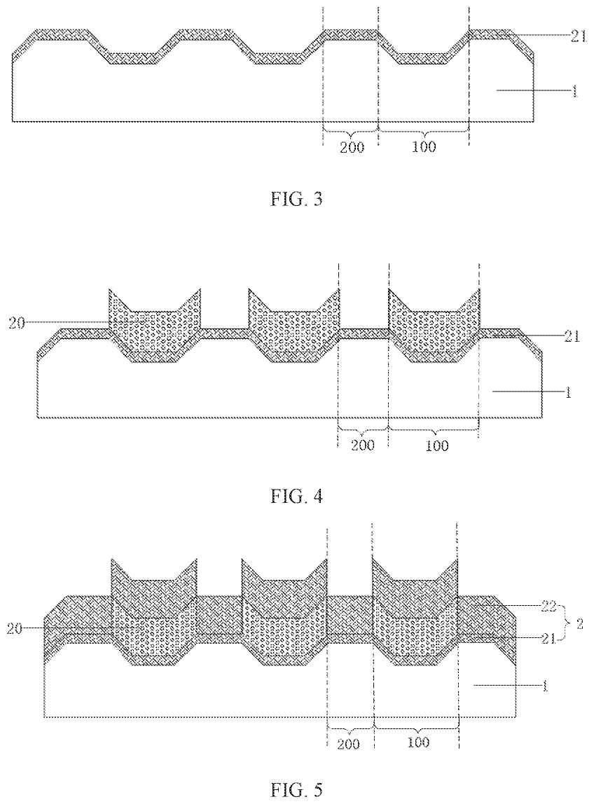

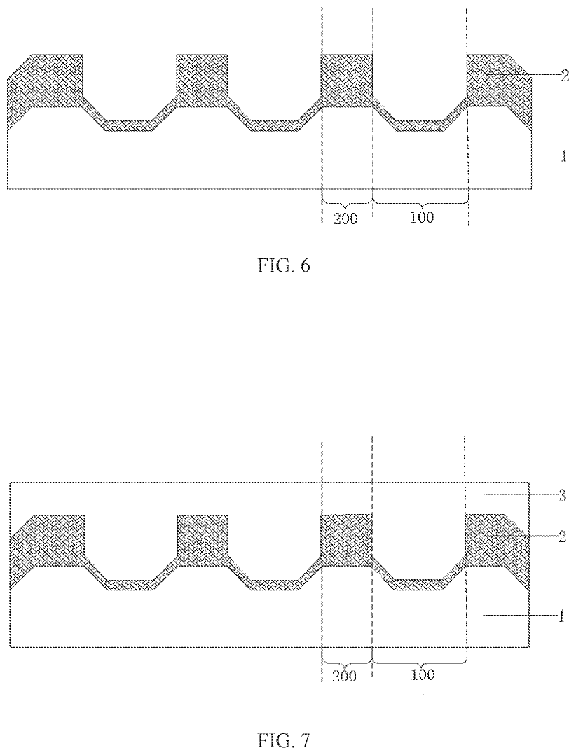

Referring to FIG. 3, it is a schematic structural view of a display panel in step S1 of the manufacturing method according to first embodiment of the present invention.

The first cathode layer 21 is evaporated by using an open mask in the step S1. A thickness of the first cathode layer 21 ranges from 100 nm to 150 nm.

Step S2: forming a maleic anhydride layer 20 on the first cathode layer 21 located in the pixel region 100.

Referring to FIG. 4, it is a schematic structural view of a display panel in step S2 of the manufacturing method according to first embodiment of the present invention.

The maleic anhydride layer 20 is formed above the pixel region 100 by inkjet printing in the step S2.

Step S3: forming a second cathode layer 22 between the pixel region 100 and the space region 200 by vapor deposition, and the second cathode layer 22 is disposed on the maleic anhydride layer 20 in the pixel region 100.

Referring to FIG. 5, it is a schematic structural view of a display panel in step S3 of the manufacturing method according to first embodiment of the present invention.

The second cathode layer 22 is evaporated by using an open mask. A thickness of the second cathode layer 22 ranges from 300 nm to 500 nm.

Step S4: the maleic anhydride layer 20 is easy sublimation, so that stripping the maleic anhydride layer 20 from the second cathode layer 22 above the pixel region, and the first cathode layer 21 formed in step S1 is retained at the pixel region 100, and the first cathode layer 21 contacted with the second cathode layer 22 is simultaneously retained in the space region, and thus a cathode layer 2 is formed.

Step S5: forming a functional layer 3.

FIG. 7 is a schematic structural view of a display panel in step S5 of the manufacturing method according to first embodiment of the present invention.

The present invention has beneficial effects described herein. A display panel and a method of manufacturing thereof are provided. The thickness of the cathode layer above the pixel region is less than the prior art, and the use of a highly transparent material as the cathode may improve the transmittance of the display panel. The thickness of the cathode layer above the space region is great than the prior art, which avoids the problem of voltage drop, thereby avoiding raising the external voltage and achieving the purpose of reducing energy consumption. In addition, the method is simple, easy to implement, and operability.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A display panel, comprising:
pixel regions spaced from each other and arranged in an array; and
a space region disposed between the pixel regions; wherein the display panel comprises a thin film transistor substrate, a cathode layer, and a functional layer disposed in order, and a thickness of the cathode layer above the pixel region is less than a thickness of the cathode layer above the space region.

2. The display panel according to claim 1, wherein the thickness of the cathode layer above the pixel region ranges from 100 nm to 150 nm.

3. The display panel according to claim 1, wherein the thickness of the cathode layer above the space region ranges from 400 nm to 600 nm.

4. The display panel according to claim 1, wherein a material of the cathode layer comprises one of magnesium alloys or silver alloys.

5. The display panel according to claim 1, wherein a light transmittance of the cathode layer above the pixel region is greater than 90%.

6. A display device comprising a body, wherein the body comprises the display panel of claim 1.

7. The display device according to claim 6, wherein the thickness of the cathode layer above the pixel region ranges from 100 nm to 150 nm.

8. The display device according to claim 6, wherein the thickness of the cathode layer above the space region ranges from 400 nm to 600 nm.

9. The display device according to claim 6, wherein a material of the cathode layer comprises one of magnesium alloys or silver alloys.

10. The display device according to claim 6, wherein a light transmittance of the cathode layer above the pixel region is greater than 90%.

11. A method of manufacturing the display panel of claim 1, comprising following steps:
step S1: providing a thin film transistor substrate, wherein the thin film transistor substrate comprises pixel regions spaced from each other and arranged in an array and a space region disposed between the pixel regions, and a first cathode layer is deposited on the thin film transistor substrate by vapor deposition;
step S2: forming a maleic anhydride layer on the first cathode layer located in the pixel region;
step S3: forming a second cathode layer between the pixel region and the space region by vapor deposition, wherein the second cathode layer is disposed on the maleic anhydride layer in the pixel region;
step S4: stripping the maleic anhydride layer from the second cathode layer above the pixel region, wherein the first cathode layer formed in step S1 is retained at the pixel region, and the first cathode layer contacted with the second cathode layer is simultaneously retained in the space region; and
step S5: forming a functional layer.

12. The method of manufacturing the display panel according to claim 11, wherein the first cathode layer is evaporated by using an open mask in the step S1.

13. The method of manufacturing the display panel according to claim 11, wherein the maleic anhydride layer is formed above the pixel region by inkjet printing in the step S2.

14. The method of manufacturing the display panel according to claim 11, wherein a thickness of the first cathode layer ranges from 100 nm to 150 nm.

15. The method of manufacturing the display panel according to claim 11, wherein a thickness of the second cathode layer ranges from 300 nm to 500 nm.
